(19) United States
(12) Patent Application Publication
(10) Pub. No.: US 2009/0256560 A1
(43) Pub. Date: Oct. 15, 2009

(54) Sensor system embedded in metal

(76) Inventor: Kunitaka Arimura, Kanagawa (JP)

Correspondence Address: JAMES C. WRAY, 1493 CHAIN BRIDGE ROAD, SUITE 300, MCLEAN, VA, 22101, US

(21) Appl. No.: 11/991,444

(22) PCT Filed: Sep. 13, 2006
(86) PCT No.: PCT/JP2006/318164

§ 371 Date: Mar. 4, 2008

(30) Foreign Application Priority Data
Sep. 13, 2005 (JP) 2005-265272

(51) Int. Cl. G01R 33/02; G01N 27/72

(52) U.S. Cl. 324/258; 324/219

(57) ABSTRACT

A sensor system, which can be embedded in a metal bed or metal face and has a good performance, has been demanded. A sensor system arranged in the following manner fulfills the above-mentioned demand. When the sensor system employs a square bracket shaped magnetic substance core, a magnetic path is formed and a strong magnetic field vertical to the metal face is obtained, even if the square bracket shaped magnetic substance core is embedded in a concave of the metal bed. A strong vertical magnetic field is obtained in the center portion of a combined magnetic substance cores even by using a surface current on the metal face.

### FIELD OF THE INVENTION

The present invention relates to a sensor system comprising an RFID tag or a sensor, which is operable in a magnetic field generated by a coil, embedded in a metal bed or a metal surface.

### RELATED BACKGROUND ART

Since a non-contact type IC card and an RFID (Radio Frequency Identification) tag having a coil therein as well as a sensor for a reader/writer used together with the IC card and the RFID tag (hereinafter these are referred as “magnetically operable sensors) are actuated in a magnetic field generated by a high frequency vibration, when the magnetically operable sensors are closed to a metal bed or metal surface their sensitivities are greatly deteriorated due to a mirror effect.

This is due to a phenomenon that the electric field or a magnetic field around the magnetically operable sensor is compensated with a generated electric field or a magnetic field by a reverse phased current due to the mirror effect (image). In other words, properties of the magnetically operable sensor are spoiled, compared with a case when the metal bed is not applied closely to the sensor. Since an electric field parallel to the metal face is zero, all free electrons filling the metal bed are observed as a surface electric current or magnetic current.

There is a structure called “on metal” in order to deviate a magnetic field by arranging a magnetic substance between the metal face and the RFID, but influence by the metal still exists.

As the applicant disclosed in reference 1, an IC tag which positively utilizes a metal face, can increase a magnetic flux density twice, namely increase a voltage twice (6dB) by the mirror effect. However, this method can intensify a magnetic field mainly in a direction along the metal face.

As the applicant disclosed in reference 2, a vertical magnetic field to the metal face is obtained by employing a non-contact type sensor coil. However, since portions of the magnetic field closest to the metal face compensate each other, there is a problem that merely a portion of a vertical component of the magnetic can be utilized.

Since cross sections of the magnetic substance core are arranged along the metal faces in the above-referred references, these are good ways to capture surface electric current. However, when the magnetically operable sensors are arranged in the metal beds, passages of the magnetic field are closed so that merely a portion of magnetic field can be leaked outside.
Reference 1: Japanese laid open patent No. 2003-317052
Reference 2: Japanese laid open patent No. 2003-318634

### DISCLOSURE OF THE INVENTION

### Problems to be Solved by the Invention

When the magnetically operable sensors are embedded in a concave formed on a metal bed, a surface electric current or a magnetic current flows into the concave via the surface of the metal. Strictly speaking this phenomenon is similar to a tunnel effect in a cut-off wave conductive pipe. However, since the concave is not so deep, almost all portions of the surface electric current or magnetic current flow into the concave, so that attenuated degrees of the electric current, magnetic field and phase delay are not so large to consider effects by such attenuated degrees.

In order to keep magnetic performances of the magnetically operable sensors embedded in the concave almost the same as when placed on the metal face, windows are formed at one end where horizontal magnetic field or vertical magnetic field flows into, so that the magnetic field can pass through along the magnetic path between the window at one end to a window formed at the other end. Alternatively, a magnetic path from which the magnetic field flows out vertically, can be formed at a intermediate portion

At present as the embedded type sensors, only sensors utilizing small magnetic fields generated by leaking magnetic fields exist. However, if the above-mentioned windows are realized, sensor systems of good performance which are completely embedded in metal can be constituted so that such sensor systems have smooth and flat appearance.

The objective of the present invention is to provide a sensor system embedded in metal which can be integrated into any product such as an in-metal tag, an in-metal sensor or the like without being noticed its presence.

### Means to Solve the Problem

In order to solve the problems mentioned above, the sensor system embedded in metal is constituted as follows.

As stated in claim 1, the sensor system embedded in metal by the present invention comprising: an IC employed as a tag or a senor; a magnetic substance core of which both end portions are curved or rectangularly bent so that the tag or the sensor is arranged between the curved or bent both end portions; and a meal bed having a concave for fitting the magnetic substance core, wherein: the magnetic substance core is wound around by a coil so as to read signals from the IC or write signals in the IC without directly contacting the IC; and the coiled magnetic substance core is fitted in the concave of the metal bed such that both ends of the magnetic substance core are arranged upward on a level with the surface of the metal bed.

As stated in claim 2, in the sensor system according to claim 1: the coil is wound around a portion of the magnetic substance core parallel to the surface of the metal bed.

As stated in claim 3, in the sensor system according to claim 1: the coil is wound around curved or rectangularly bent end portions of the magnetic substance core.

As stated in claim 4, the sensor system according to claim 1 further comprising another magnetic substance core, wherein: another magnetic substance is contacted to the magnetic substance core in series; and the coil is wound around such that far ends of both magnetic substance cores respectively have opposite magnetic poles.

As stated in claim 5, the sensor system according to claim 1 further comprising another magnetic substance core, wherein: another magnetic substance core is contacted to the magnetic substance core in series; and the coil is wound around such that respective far ends of both magnetic substance cores have the same magnetic poles and contacting ends in the center of the both magnetic substance cores have opposite magnetic poles to the magnetic pole of the far ends.

As stated in claim 6, in the sensor system according to claim 1: five faces of the magnetic substance core are covered with metal plates except a face toward the ends of the magnetic substance core arranged on a level of the surface of the metal bed.

As stated in claim 7, in the sensor system according to claim 1: the sensor system is attached to a reader/writer.

As stated in claim 8, in the sensor system according to claim 1: a sensor device is further mounted in a residual space between end portions of the magnetic substance core.

As stated in claim 9, in the sensor system according to claim 1: a super capacitor or a capacitor with a large capacity and a cell are mounted so as to work the sensor system as an active tag.

As stated in claim 10, in the sensor system according to claim 1: the sensor system is sealed with a ceramic or a plastic.

As stated in claim 11, in the sensor system according to claim 1: an upper portion of the concave is formed in the metal bed a little bit wider than a lower portion of the concave so as to insert the tag or sensor into the concave more easily.

As stated in claim 12, in the sensor system according to claim 1: an upper portion of the tag or sensor is formed a little bit wider than a lower portion of the tag or sensor so as to insert the tag or sensor into the concave formed in the metal bed more easily.

As stated in claim 13, in the sensor system according to claim 1: a locking mechanism is arranged so as to secure the tag or sensor to the concave.

### Effects Attained by the Invention

Since usually magnetic fields cannot get in inside of the metal face except magnetic fields at low frequencies, the magnetic substance core is put in the concave on the metal face such that both ends of magnetic poles are arranged on level of the metal face. The coil is wound around the magnetic substance core in order to capture signals from the IC. The IC functioning as the tag or the sensor is fitted to the coiled core. Since the tag or the sensor is buried under the metal face, the sensor system by the present invention keeps a good appearance without being noticed its presence, and can be perform various functions such as detecting a metal object, controlling a system, tracing a moving object, maintenance of a system and the like.

### BRIEF DESCRIPTIONS OF THE DRAWINGS

FIG. 1 is schematic cross-sectional views illustrating examples of conventional tags.

FIG. 2 is schematic cross-sectional views illustrating examples of tags of the present invention.

FIG. 3 is perspective views illustrating magnetic substance cores wound around by coils of the present invention.

FIG. 4 is a perspective view illustrating an IC tag embedded in metal by the present invention.

FIG. 5 is schematic diagram illustrating electric currents and magnetic field in and around a small concave formed in metal.

FIG. 6 is a schematic perspective view for explaining an operational behavior of a tag or a sensor.

FIG. 7 is a schematic perspective view for explaining operational behavior of an example of the tag or the sensor having a dual core system.

FIG. 8 is schematic views of multi-polar core systems used for the tag or the sensor.

FIG. 9 is a schematic perspective view for illustrating how to apply the magnetic substance core to a metal plate or a metal foil.

FIG. 10 is schematic perspective views illustrating metal cases for enclosing the magnetic substance core.

FIG. 11 is schematic views of a sensor module and a metal bed in which the sensor module is integrated.

FIG. 12 is perspective views of examples of active tags.

FIG. 13 is a schematic view of an embodied example of the embedded sensors by the present invention.

FIG. 14 is a schematic view of the other embodied example of the embedded sensors by the present invention.

FIG. 15 is a schematic view illustrating an applied example of the embedded sensors.

FIG. 16 is a schematic view illustrating a relation between an electric current and a magnetic field around the dual core system.

FIG. 17 is diagrams illustrating various coil winding manners.

FIG. 18 is a perspective view illustrating an example of the active tags having a capacitor or a cell in concave spaces of the cores.

FIG. 19 is a perspective view illustrating an example of the active tags having a sensor as well as capacitor or a cell in concave spaces of the cores.

FIG. 20 is a perspective view of a modularized sensor tag.

FIG. 21 is a schematic diagram of an applied example of the sensor tags.

### PREFERRED EMBODIMENTS BY THE PRESENT INVENTION

Hereinafter, the preferred embodiments by the present invention are explained in details.

### Embodiment

Hereinafter examples of the embedded tags and sensor system in metal are explained as referring to drawings.

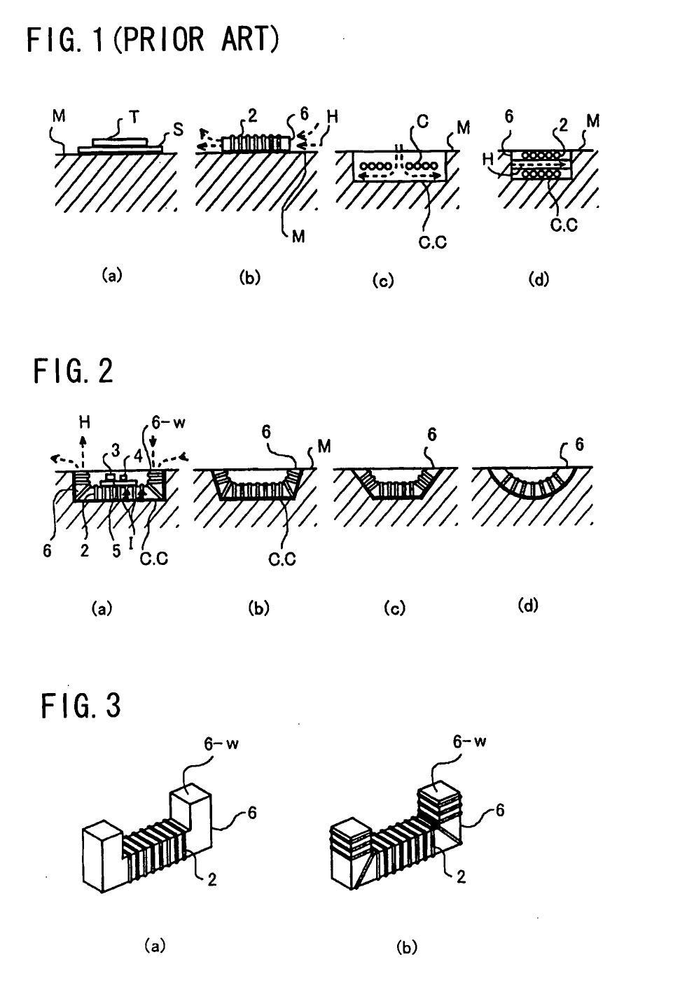

FIG. 1 is schematic cross-sectional views illustrating examples of conventional tags. In FIG. 1 (a), an ordinary coil type tag T is arranged on a metal face M via a magnetic substance sheet S which generates magnetic paths so that performance of the tag T is suppressed from being deteriorated to a certain extent.

FIG. 1 (b) shows an example of the tags described in reference 1. The tag comprising a magnetic substance 6 wound around by a coil 2 is arranged on a metal surface M, so that strong magnetic field is generated along the metal face and works effectively. However, when the tag is put in a concave C.C below the metal face M as shown in FIG. 1 (c), exits of the generated magnetic field are closed.

FIGS. 1 (c) and (d) illustrate tags utilizing mirror effects described in reference 1. These tags work effectively when arranged on the metal face M. However, when the tags are embedded in the concave C.C below the metal face M as illustrated in FIG. 1 (d), ends of magnetic poles are closed by the metal, so that most intensive portions of the magnetic field collide with metal walls. As a result the magnetic field cannot get out of the metal face M, but merely a portion of the magnetic field can leak out of the metal face M.

FIG. 1 (c) illustrates an ordinary circular tag where a coil C is wound in a radial direction. The tag works very little due to a mirror effect of the metal. Even if the mirror effect is compensated by a magnetic substance more or less, most portions of magnetic field generated in a radial direction of the coil are collide with metal walls, so that merely a portion of the generated magnetic field gets out of the metal face M.

Consequently, conventional tags illustrated in FIG. 1 cannot be used as embedded tags in metal. However, when tags are embedded in manners as illustrated in FIG. 2, the tags can capture a magnetic field (magnetic current) or on electric current which flows on the metal face.

FIG. 2 is schematic cross-sectional views illustrating examples of tags or sensors by the present invention. In FIG. 2 (a), a square bracket shaped magnetic substance core 6 formed out of a square rod having bent both ends and the magnetic substance is embedded in a concave C.C as both ends being upright. In the tag, an induction voltage is generated in a coil 2 by a magnetic field H getting in vertically to one magnetic pole 6-w, passing through a horizontal portion of the core 6 and getting out of the other magnetic pole 6-w, or by a facial magnetic current H. Alternatively, it is also thought that magnetic field H generated by an electric current I flowing through the coil 2 generates magnetic field above the magnetic poles and band magnetic current along metal face as the magnetic field passing through a magnetic path. These are the same phenomena, whether the tag receives the magnetic field or transmits the magnetic field.

Data are written in or read out of an IC 3 attached to the coil 2 by an electric current generated by a voltage induced in the coil 2. Usually the IC is mounted on a substrate 5 or packaged. The IC 3 or an IC package is directly connected to the substrate 5 via an insulator. Sometimes a capacitor 4 having a small capacity is mounted on the substrate for tuning, FSK (frequency shift keying) or the like.

As shown in FIG. 2, since the tag does not protrude from the metal face, it can be arranged not being observed from outside when a position on the surface corresponding to the tag is covered by potting or covered with a cap made of plastic or ceramic.

In FIG. 2 (b), both ends of the concave C.C are slanted outward so as to easily bury the core 6. Both ends of the core 6 are also slanted in accordance with the geometry (i.e. reversed trapezoid) of the concave C.C. Both ends of the concave illustrated in FIG. 2 (c) are slanted more. In this case, a tag or a senor is inserted into the concave more easily, but the inserted tag or the sensor easily apt to get out of the concave. In the slanted cores illustrated in FIG. 2 (b) and FIG. 2 (c), since generated slanted magnetic field has a horizontal component, the generated magnetic field is connected with a surface magnetic current well, but a vertical component of the magnetic field is somewhat reduced.

The concave illustrated in FIG. 2 (d) have an arc-shaped cross-section, so that the core is formed circularly in accordance with the shape of the concave.

FIG. 3 is the perspective view of magnetic substance cores 6 wound around by coil 2. In FIG. 3 (a), a horizontal middle portion of the square bracket shaped magnetic substance core 6 is wound around by the coil 2 in order to generate a magnetic field. The generated magnetic field passes through the middle portion of the core in a horizontal direction and gets out into space via one end 6-w functioning as a magnetic pole after passing through a vertical portion of the magnetic substance core 6. (If the core 6 is erected, the generated magnetic field passes through the middle portion of the core 6 in a vertical direction.)

In FIG. 3 (b), the coil 2 is wound around both vertical ends of the magnetic substance core 6 as well as the horizontal middle portion. As a result a magnetomotive force of the core is strengthened, so that a more intensive magnetic field is generated.

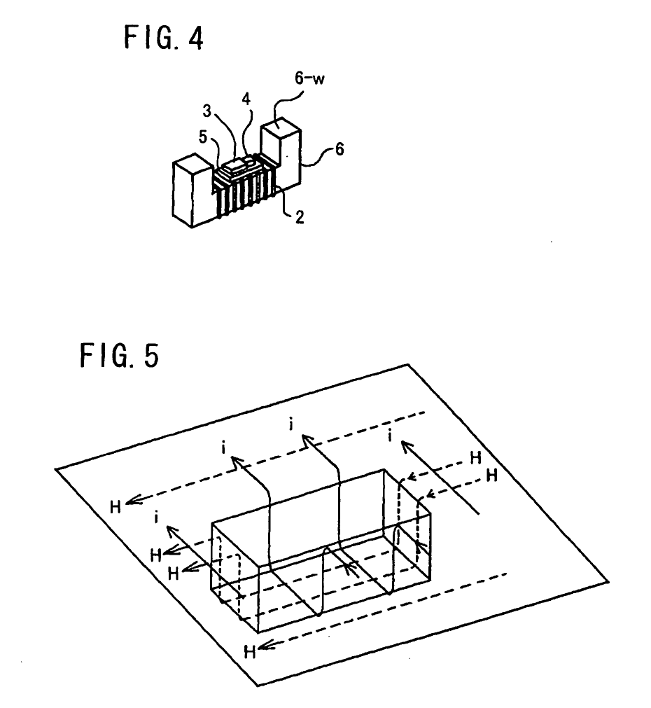

FIG. 4 is the perspective view illustrating the metal embedding type IC tag. The IC tag comprises an IC 3 and a capacitor 4 connected via a substrate 5 to the square bracket shaped magnetic substance core 6 illustrated in FIG. 3 (a). The IC 3, the capacitor 4 and the substrate 5 are accommodated in a concave portion of the square bracket shaped magnetic substance core 6.

FIG. 5 is schematic diagram illustrating electric currents and a magnetic field in and around the small concave formed in metal.

If a depth or a length of the small concave is about from ¼ to ½ wave length of a transmitted signal from or received signal by the IC 3, an electric current pattern and a magnetic field pattern are quite different from the patterns illustrated in FIG. 5. However, in the present invention, since the depth or the length of the concave is much smaller than the wavelength, electric current on the metal surface is not disturbed by the signal so much. As a result, the electric current i has a continuous pattern, so that the generated magnetic field H in accordance with the electric pattern gets in the concave as shown in FIG. 5.

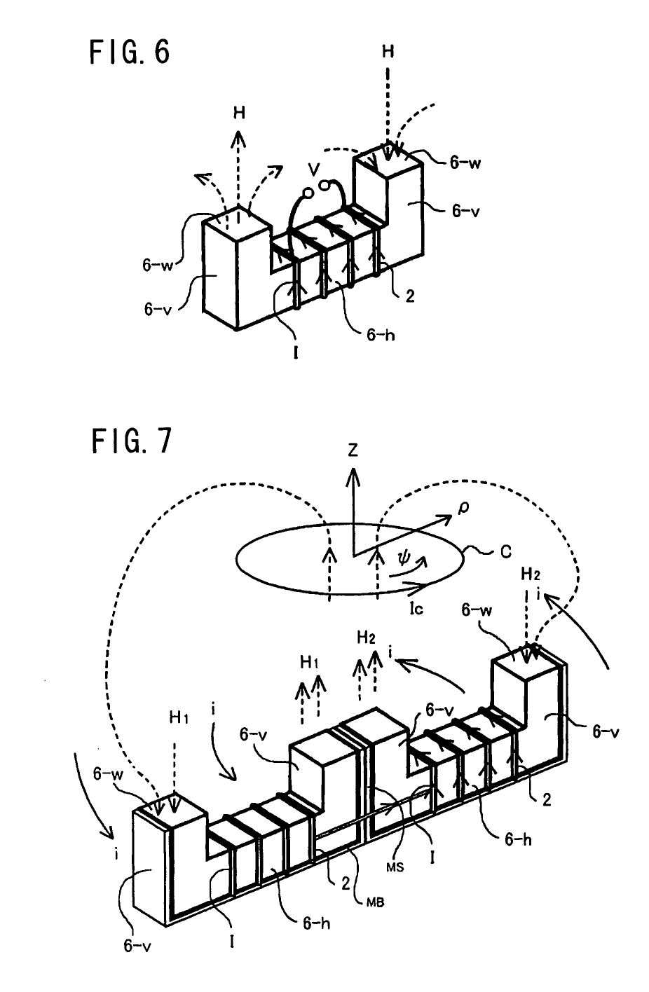

FIG. 6 is the schematic perspective view for explaining operational behavior of the tag or the sensor. In the square bracket shaped magnetic substance core 6, the magnetic field H gets in the magnetic substance core 6 via the end of one magnetic pole 6-w on the right side, passes through a vertical magnetic path 6-v and a horizontal magnetic path 6-h, and finally gets out of the end of other magnetic pole 6-w on the left side. A voltage V induced as the magnetic field passing through the horizontal magnetic path 6-h is applied to the IC (not shown in FIG. 6), so that a signal is generated from the IC. The generated signal is applied to the coil 2 so that a magnetic field H is generated and gets out of the end of the magnetic pole 6-w. The signal generated from the tag in the above-mentioned manner can be captured by an externally arranged coil or sensor.

The arrangement illustrated in FIG. 6 is a simple example having one magnetic substance core, and only the horizontal magnetic field passes through the middle portion of the core. However, sometimes it is required to generate intensive magnetic fields vertical to metal face in the middle of card readers/writers having coils or tags for such readers/writers.

FIG. 7 is the schematic perspective view for explaining operational behavior of other example of the tag or sensor which generates a vertical magnetic field (Jet field).

A magnetic field generated by an upper coil (loop) C flows along the metal face in a width or a radial (ρ) direction in cylindrical coordinates. On the other hand a surface electric current flows in the same direction (designated as ψ) as a flowing direction of an electric current Ic flowing in the coil C.

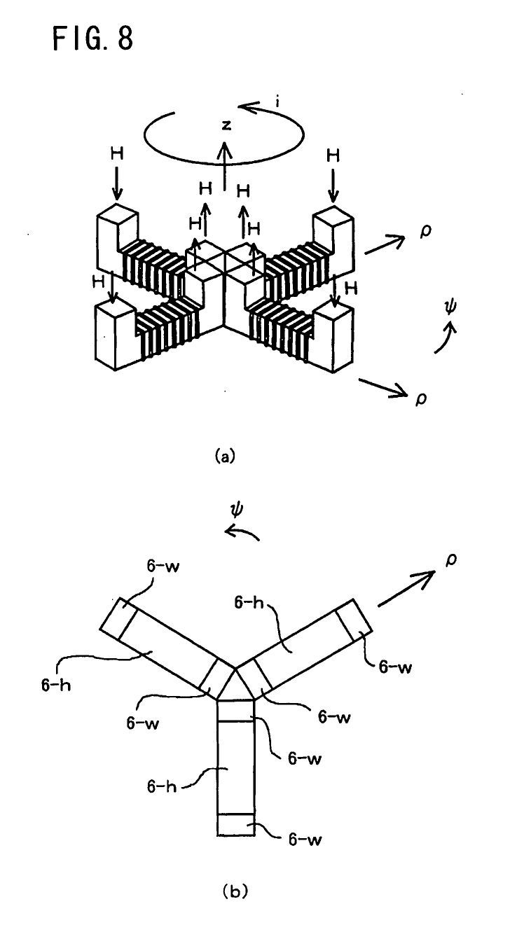

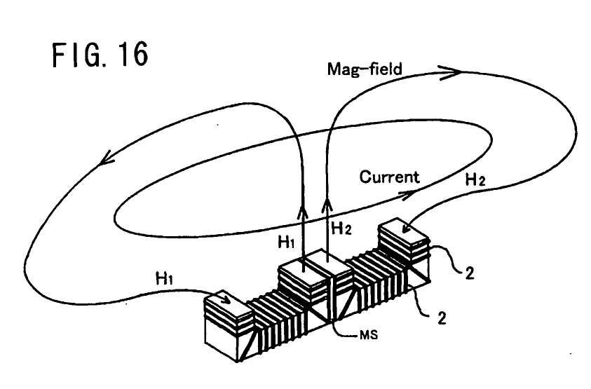

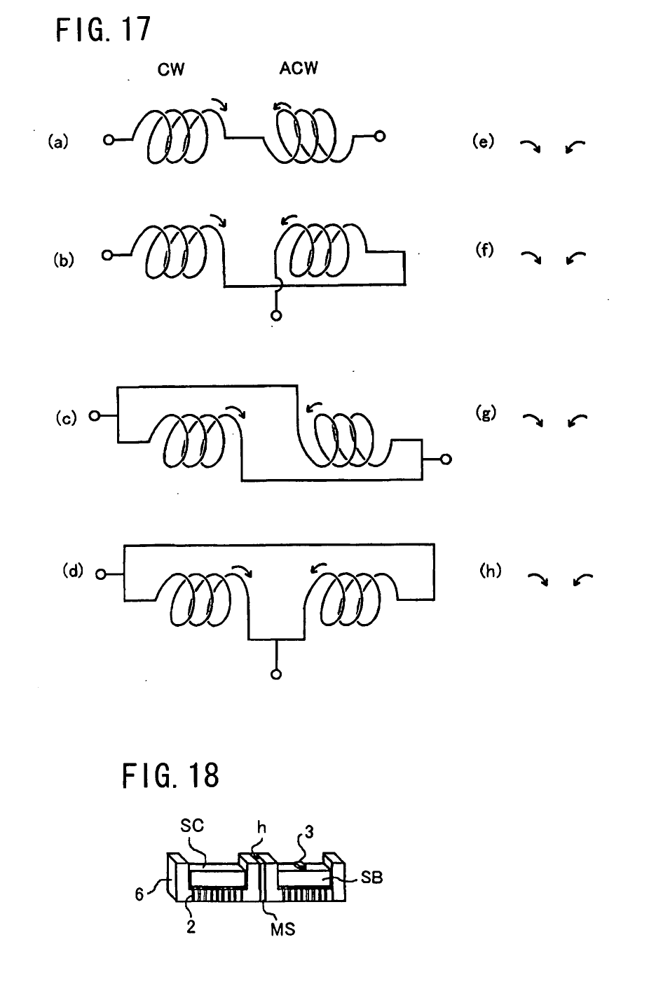

As shown in FIG. 7, magnetic poles on both ends are the same pole. A portion of the magnetic field getting in the magnetic poles 6-w on both ends respectively flow through vertical magnetic paths 6-v, and further flow through horizontal magnetic paths 6-h so that induction voltages are generated in the respective coils 2. Then the magnetic field gets out of the magnetic pole as illustrated by upward arrows H₁, H₂ after passing through vertical magnetic paths in the middle. Therefore, intensive vertical magnetic field can be generated in the center of the sensor, and generated magnetic field are strongly connected with the upper coil (loop) C. Details will be explained as referring to FIGS. 16, 17 later. The core system illustrated in FIG. 7 comprises two cores (hereinafter referred as “a dual core system”), but a multi-core system or an increased core system is also possible, which will be explained hereinafter as referring to FIG. 8.

FIG. 8 is the schematic views of multi-polar core systems used for the tag or the sensor system. In FIG. 8 (a), a four core system for the tag or the sensor is illustrated as an example of the even-numbered core systems. In FIG. 8 (b), a three core system for the tag or the sensor is illustrated as an example of the odd-numbered core systems. In both core systems, cores are axisymmetrically arranged in a width or a radial (ρ) direction. In a cylindrical coordinate system, a magnetic field on the metal surface is excited mainly in the radial (width) direction and a surface electric current i flows in a ψ direction. A magnetic field H is generated by the upper coil mainly in a Z direction.

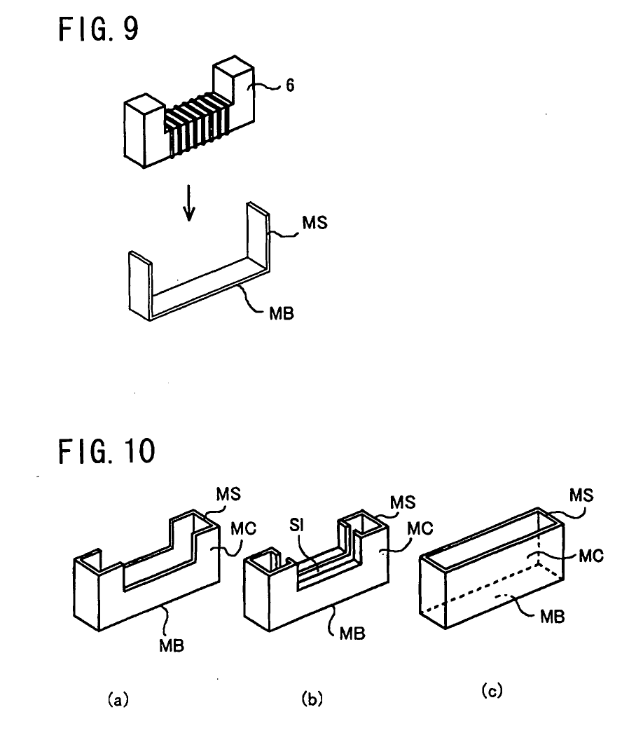

FIG. 9 is the schematic perspective view for illustrating how to apply the magnetic substance core 6 to a square bracket shaped metal plate (or a metal foil) consisting of a horizontal member MB and two vertical members MS. The metal plate is attached to the tag or the sensor before the tag or the sensor is inserted into the concave of the metal bed. When the tag or the sensor is buried in the metal bed, an inductance and a capacitance of the tag or the censor are varied. A tuning frequency of the tag or sensor is also varied and frequencies are varied in the case of the FSK.

The metal plate illustrated in FIG. 9 is a simple example. In order to control a magnetic field around the tag or sensor more properly, more complicated structured metal plates (or case) as illustrated in FIG. 10 are required.

FIG. 10 is perspective views illustrating metal cases for enclosing the core. Compared with the case illustrated in FIG. 9, the case illustrated in FIG. 10 (a) has additional side plates MC facing sides of the coil and the core. Further the case illustrated in FIG. 10 (b) has a cover so as to incompletely enclose the coil and the core, which is very important feature to keep the coil and the core active such that an electric current in the coil generates a magnetic field which causes an induction voltage and electric current. Fur that purpose, a slit SI should be formed on the cover.

If the slit is not formed, namely, if the coil and the core is completely enclosed, the magnetic field does not get in inside and no electric current is generated in the coil.

In FIG. 10 (c), a metal box without a top cover is illustrated. The metal box has five faces, namely the box has no top face, so that the magnetic field can get in inside. The coil and the tag are completely buried in this box so that a modularized sensor system is provided. Instead of the metal plate, a metal foil, a metal deposition or the like may be employed.

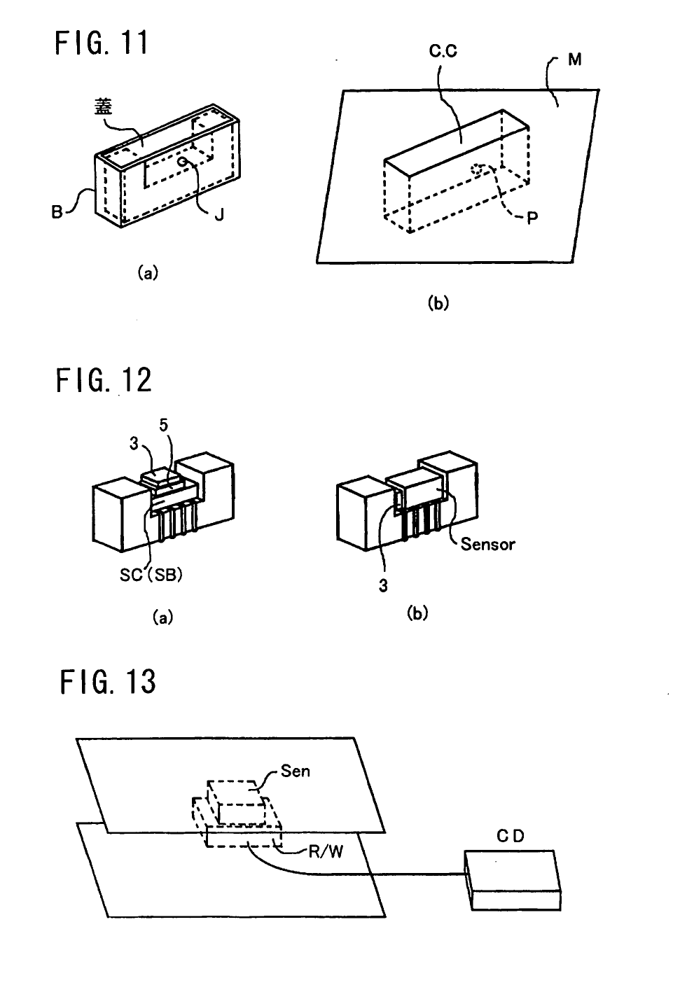

FIG. 11 is schematic views of a sensor module and a metal bed in which the sensor module is integrated. After the tag or the sensor is accommodated in a metal box B illustrated in FIG. 11 (a), the top is covered with a material such as plastic or ceramic which does not influence magnetic and electrical properties of the tag or the sensor, thus a sensor module is completed. The completed module is placed in and fixed to a concave C.C formed in a metal bed or a metal face M as illustrated in FIG. 11 (b).

The module is firmly fixed to the concave C.C by mating a protrusion J formed on the side face of the box B to a recess P formed in the metal bed. Alternatively, adhesives or screws may be employed for fixing the module.

FIG. 12 is perspective views of examples of the active tags. In FIG. 12 (a), the active tag comprises a super (large capacity) capacitor SC and a cell SB arranged between the two magnetic poles. In some cases, only the capacitor SC may be arranged, and a primary or a secondary cell may be employed as the cell SB.

In FIG. 11 (b), a sensor is arranged between the two magnetic poles of the active tag and vibration data, temperature data or the like captured by the sensor may be recorded in the IC 3.

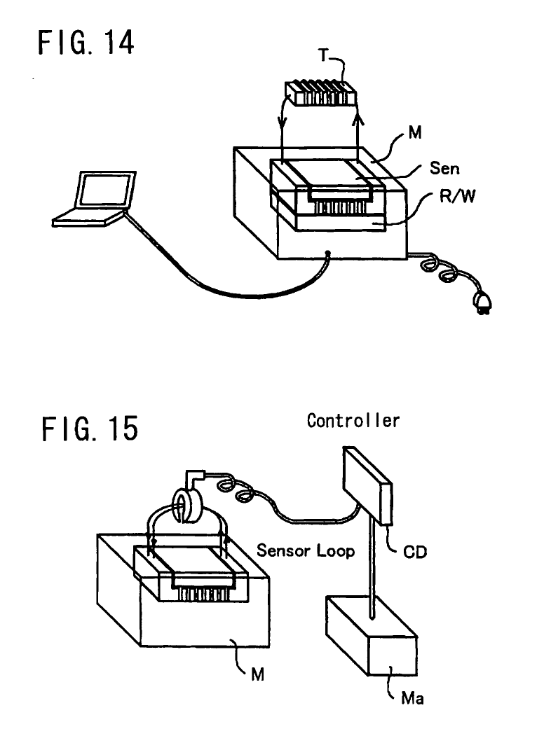

Embodied examples of the embedded sensors by the present invention are illustrated in FIGS. 13 and 14. In FIG. 13, a sensor Sen is buried under the surface of the metal bed so that the sensor Sen is not observed outside. Signals from the sensor are connected to a control device CD via a reader/writer R/W.

In FIG. 14, the sensor Sen arranged in two magnetic poles of the magnetic substance attached to the reader/writer R/W and the reader/writer R/W are buried in the metal bed M. The magnetic substance core is connected to a tag T arranged upward. The sensor system is connected to a note type (personal) computer, which reads captured data by the sensor system.

FIG. 15 is the schematic view illustrating the applied example of the embedded sensor. Here, signals from the tag buried in the metal bed M are read by the control device CD via a sensor loop and read signals are transmitted to a machine Ma.

Hereinafter, embodiments which employ the dual core system as illustrated in FIG. 7 are explained in detail.

FIG. 16 is the schematic view illustrating a relation between the electric current and the magnetic field around the dual core. As shown in the figure, the coil 2 is continuously wound around not only horizontal portions of the cores but also vertical portions of the cores. In order to obtain a magnetic field illustrated in FIG. 16, the coil 2 should be wound in one of the manners illustrated in FIG. 17.

FIG. 17 illustrates various coil winding manners. In FIG. 17 (a), the coil 2 is wound clockwise (CW) around the core on the left side and it is assumed that the magnetic field H₁ gets out of the right pole and gets in the left pole as illustrated in FIG. 16 when an electric current flows as shown in FIG. 17 (a).

The coil 2 is wound counterclockwise (ACW) around the core on the right side and the electric current flows in the same direction but counterclockwise as shown in FIG. 17 (a), so that the magnetic field H₂ gets out of the left pole and gets in the right pole as illustrated in FIG. 16. In this manner, the vertical magnetic fields with the same intensity and the same directions are obtained vertical to the metal surface in the central area of the dual core. In order to prevent magnetic field leakage and to isolate the two cores, an intermediate metal plate MS is arranged between the two cores as illustrated in FIG. 16. It is securer to arrange such plate, but in some cases, it may be omitted from a practical point of view.

In FIG. 17 (b), the coil is wound clockwise around the left and right cores, but the electric current flows in the opposite directions each other.

In FIG. 17 (c), the left side core and the right side core are electrically connected in parallel, while the two cores are connected in series in FIG. 17 (a).

In FIG. 17 (d), the left side core and the right side core are electrically connected in parallel, while the two cores are connected in series in FIG. 17 (b).

FIG. 18 is the perspective view illustrating an example of the active tags having a super capacitor (with large capacity) SC and a secondary cell SB in concave spaces of the cores 6. A hole h, through which a bolt is threaded for fixing the tag module, may be formed in the intermediate metal plate MS.

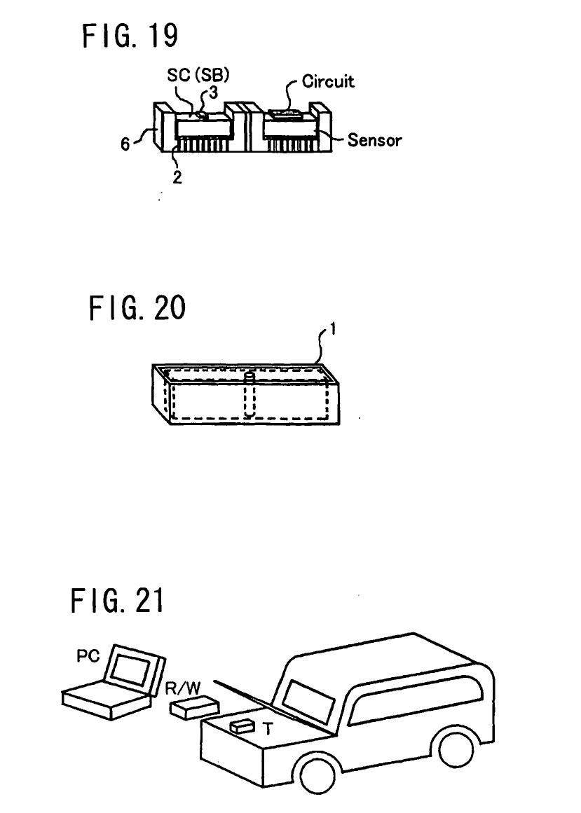

FIG. 19 is a perspective view illustrating another example of the active tags having a sensor and a circuit in addition to the super capacitor SC or the cell SB in concave spaces of the cores 6 illustrated in FIG. 18.

FIG. 20 is the perspective view of the modularized sensor tag. As the example illustrated in FIG. 11, a sensor system is accommodated in a metal box 1 so as to modularize the sensor system.

FIG. 21 is the schematic diagram of the applied example of the sensor tags. In this drawing, a sensor tag T is fitted to a car and data can be read by a computer PC via a reader/writer R/W. In the similar way, the tag T may be fitted to a bike, a machine, a weapon, an airplane and the like.

As explained above, even if the tag and the sensor system is embedded in metal, but some portions of the tag or the sensor system are opened to outside, the reader/writer or the computer can read data in the tag or signals from the sensor system by capturing a magnetic field or an electric current through the opened portions.

Also as explained above, since the intensive magnetic field vertical to metal face can be obtained by employing two or more cores, reliable tags or sensor systems embedded in metal can realized, so that the tags or sensor systems by the present invention can be applied to various industries, which is a great advantage of the present invention.

What is claimed is:

1. A sensor system embedded in metal comprising:
an IC employed as a tag or a senor;
a magnetic substance core of which both end portions are curved or rectangularly bent so that said tag or said sensor is arranged between the curved or bent both end portions; and
a meal bed having a concave for fitting said magnetic substance core, wherein:
said magnetic substance core is wound around by a coil so as to read signals from said IC or write signals in said IC without directly contacting said IC; and
said coiled magnetic substance core is fitted in said concave of said metal bed such that both ends of said magnetic substance core are arranged upward on a level with the surface of said metal bed.

2. The sensor system according to claim 1, wherein:
said coil is wound around a portion of said magnetic substance core parallel to the surface of said metal bed.

3. The sensor system according to claim 1, wherein:
said coil is wound around curved or rectangularly bent end portions of said magnetic substance core.

4. The sensor system according to claim 1, further comprising another magnetic substance core, wherein:
said another magnetic substance is contacted to said magnetic substance core in series; and
said coil is wound around such that far ends of both magnetic substance cores respectively have opposite magnetic poles.

5. The sensor system according to claim 1, further comprising another magnetic substance core, wherein:
said another magnetic substance core is contacted to said magnetic substance core in series; and
the coil is wound around such that respective far ends of both magnetic substance cores have the same magnetic poles and contacting ends in the center of the both magnetic substance cores have opposite magnetic poles to the magnetic pole of the far ends.

6. The sensor system according to claim 1, wherein:
five faces of said magnetic substance core are covered with metal plates except a face toward the ends of the magnetic substance core arranged on a level of the surface of said metal bed.

7. The sensor system according to claim 1, wherein:
said sensor system is attached to a reader/writer.

8. The sensor system according to claim 1, wherein:
a sensor device is further mounted in a residual space between end portions of said magnetic substance core.

9. The sensor system according to claim 1, wherein:
a super capacitor or a capacitor with a large capacity and a cell are mounted so as to work said sensor system as an active tag.

10. The sensor system according to claim 1, wherein:
said sensor system is sealed with a ceramic or a plastic.

11. The sensor system according to claim 1, wherein:
an upper portion of the concave is formed in said metal bed a little bit wider than a lower portion of the concave so as to insert said tag or sensor into the concave more easily.

12. The sensor system according to claim 1, wherein:
an upper portion of said tag or sensor is formed a little bit wider than a lower portion of said tag or sensor so as to insert said tag or sensor into the concave formed in said metal bed more easily.

13. The sensor system according to claim 1, wherein:
a locking mechanism is arranged so as to secure said tag or sensor to the concave.
